(19) United States
(12) Patent Application Publication
(10) Pub. No.: US 2016/0284589 A1
(43) Pub. Date: Sep. 29, 2016

(54) Layer Transfer Technology for Silicon Carbide

(71) Applicants: Stratio, Seoul (KR); Stratio, Inc., San Jose, CA (US)

(72) Inventors: Jae Hyung LEE, Palo Alto, CA (US); Wooshik Jung, San Jose, CA (US)

(21) Appl. No.: 15/172,063

(22) Filed: Jun. 2, 2016

Related U.S. Application Data
(63) Continuation of application No. PCT/US2014/068179, filed on Dec. 2, 2014.
(60) Provisional application No. 61/910,717, filed on Dec. 2, 2013.

(51) Int. Cl. H01L 21/762; H01L 21/31; H01L 29/36; H01L 21/02; H01L 29/06; H01L 29/16

(52) U.S. Cl. CPC H01L 21/76254; H01L 29/0649; H01L 29/1608; H01L 29/36; H01L 21/02529; H01L 21/31; H01L 21/02381; H01L 21/02694

(57) ABSTRACT

Devices that include a layer of silicon carbide and methods for making such devices are disclosed. A method includes obtaining a first silicon carbide wafer implanted with protons; applying a first layer of spin-on-glass over the first silicon carbide wafer; obtaining a first semiconductor substrate; bonding (i) the first layer of spin-on-glass to (ii) the first semiconductor substrate; and heating the first silicon carbide wafer to initiate splitting of the first silicon carbide wafer so that a first layer of silicon carbide remains over the first semiconductor substrate. A semiconductor device includes a semiconductor substrate; a first layer of spin-on-glass positioned over the semiconductor substrate; a first layer of silicon carbide positioned over the first layer of spin-on-glass; a second layer of spin-on-glass positioned over the first layer of silicon carbide; and a second layer of silicon carbide positioned over the second layer of spin-on-glass.

### RELATED APPLICATIONS

This application is a continuation application of International Application No. PCT/US2014/068179, filed Dec. 2, 2014, which claims priority to, and benefit of, U.S. Provisional Patent Application Ser. No. 61/910,717, filed Dec. 2, 2013, both of which are incorporated by reference herein in their entireties.

### TECHNICAL FIELD

This application relates generally to semiconductor devices and methods for fabricating semiconductor devices. More particularly, the disclosed embodiments relate to semiconductor devices that include a silicon carbide layer and methods for fabricating semiconductor devices that include a silicon carbide layer.

### BACKGROUND

Electricity accounted for 40% of primary energy consumption in the United States in 2011. Power electronics are projected to play a significant and growing role in the delivery of this electricity, and it has been estimated that as much as 80% of electricity could pass through power electronics between generation and consumption by 2030 (30% of electrical energy passes through power electronics converters today). Technical advances in power electronics promise enormous energy efficiency gains throughout the United States economy. Beneficiaries of these potential improvements include motor drive, automotive, and electric power generation industries. Achieving high power conversion efficiency in these systems requires low-loss power semiconductor switches. Today's incumbent power semiconductor switch technology is silicon (Si) based metal-oxide-semiconductor field-effect transistors (MOSFETs), insulated-gate bipolar transistors (IGBTs) and thyristors. Silicon power semiconductor devices have several important limitations such as high losses, low switching frequency, and poor high temperature performance.

Silicon Carbide (SiC) MOSFETs are considered superior to silicon IGBTs in some aspects because of their high input impedance and low dynamic power dissipation. A SiC MOSFET reduces switching losses compared to Si MOSFETs and IGBTs. One reason may be that the high voltage SiC MOSFET does not have the tail current losses found in IGBTs. In addition, the high current density and small die size of SiC MOSFETs may result in lower capacitance compared to Si MOSFETs. The typical SiC MOSFET output characteristic curve already meets the industry requirements in terms of Drain-Source Breakdown Voltage, Continuous Drain Current Rating, and Operating Junction Temperature.

However, widespread use of SiC MOSFETs cannot be achieved until the cost of the device is reduced significantly. Substrates comprise a large percentage of the manufacturing cost for SiC MOSFETS. As of 2012, the substrate costs accounted for 74% of the final cost of SiC LED lighting devices. Although silicon-carbide-on-insulator (SiCOI) substrates have been considered as an alternative to SiC substrates, costs of SiCOI substrates have not been less than costs of SiC substrates.

### SUMMARY

Thus, there is a need for a cost effective method of providing a substrate with a layer of silicon carbide.

A number of embodiments (e.g., of server systems, client systems or devices, and methods of operating such systems or devices) that overcome the limitations and disadvantages described above are presented in more detail below. These embodiments provide devices with transferred silicon carbide layers and methods for transferring silicon carbide layers.

As described in more detail below, some embodiments involve a method that includes obtaining a first silicon carbide wafer implanted with protons (also called herein hydrogen-implanted); applying a first layer of spin-on-glass over the first silicon carbide wafer; obtaining a first semiconductor substrate; bonding (i) the first layer of spin-on-glass applied over the first silicon carbide wafer to (ii) the first semiconductor substrate; and heating the first silicon carbide wafer to initiate splitting of the first silicon carbide wafer so that a first layer of silicon carbide remains over the first semiconductor substrate.

In accordance with some embodiments, a method includes obtaining a first silicon carbide wafer implanted with protons; obtaining a first semiconductor substrate; applying a first layer of spin-on-glass over the first semiconductor substrate; bonding (i) the first silicon carbide wafer to (ii) the first layer of spin-on-glass; and heating the first silicon carbide wafer to initiate splitting of the first silicon carbide wafer so that a first layer of silicon carbide remains on the first layer of spin-on-glass.

In accordance with some embodiments, a semiconductor device includes a semiconductor substrate; a first layer of spin-on-glass positioned over the semiconductor substrate; a first layer of silicon carbide positioned over the first layer of spin-on-glass; a second layer of spin-on-glass positioned over the first layer of silicon carbide; and a second layer of silicon carbide positioned over the second layer of spin-on-glass.

### BRIEF DESCRIPTION OF THE DRAWINGS

For a better understanding of the aforementioned aspects as well as additional aspects and embodiments thereof, reference should be made to the Description of Embodiments below, in conjunction with the following drawings.

FIGS. 1A-1E are partial cross-sectional views of a silicon carbide wafer in accordance with some embodiments.

FIGS. 1F-1I are partial cross-sectional views of a semiconductor substrate in accordance with some embodiments.

FIGS. 1J-1N are partial cross-sectional views of a silicon carbide wafer in accordance with some embodiments.

FIGS. 1O-1R are partial cross-sectional views of a semiconductor substrate in accordance with some embodiments.

FIGS. 2A-2F are partial cross-sectional views of a semiconductor substrate in accordance with some embodiments.

FIGS. 3A-3D are partial cross-sectional views of a semiconductor substrate in accordance with some embodiments.

FIG. 4 is a partial cross-sectional view of a semiconductor device in accordance with some embodiments.

FIGS. 5A-5C are flow diagrams illustrating a method of transferring a layer of silicon carbide onto a semiconductor substrate in accordance with some embodiments.

FIG. 6 is a flow diagram illustrating a method of transferring a layer of silicon carbide onto a semiconductor substrate in accordance with some embodiments.

Like reference numerals refer to corresponding parts throughout the figures.

Unless noted otherwise, the figures are not drawn to scale.

### DESCRIPTION OF EMBODIMENTS

In the wider electronics industry, the main driver of the growing demand for silicon on insulator (SOI) substrate was its superior performance in terms of speed and power consumption, which became increasingly critical as transistor sizes shrank. Currently, SOI substrates are mainly used in the production of computer micro-processors, but the use of SOI substrates is expanding into game consoles and other devices requiring its superior performance characteristics.

In recent years, the popularity of SiC substrates has also risen, thanks to their low dynamic power dissipation, higher current density, higher power density, and higher operating temperatures. SiCOI is a superior substrate compared to SiC bulk substrate in terms of speed and power consumption. However, no wafer manufacturer has produced SiCOI wafers cost-effectively. Furthermore, the surface finish requirements for bonding these various layers is extremely challenging to achieve using existing planarization (such as chemical-mechanical-polishing, CMP) technologies.

To resolve the problems mentioned above, examples described herein include a streamlined and cost-effective way to produce SiCOI substrates. In some embodiments, such SiCOI substrates are used for high performance SiC MOSFETs. Examples utilize thin film layer transfer technology to manufacture SiCOI substrates. Multiple thin-film layer transfers may be achieved with a single substrate, significantly lowering costs associated with the SiCOI substrate. The development of multiple-times smart-cut layer transfers using SoG allows manufacturing of inexpensive SiCOI substrates. Repeated “smart-cut”-type layer transfer of single-crystal SiC is performed in some examples by applying spin-on-glass (SoG) technology to the SiC substrate.

SiC is the leading material for high voltage, high power electronics as well as an enabling material for microsystems technology operating in harsh environments. Despite the compelling materials advantage, SiC technology remains expensive, hindering its penetration into many markets. A key reason is the fact that SiC wafers are significantly more costly than Si, accounting for a large fraction of the device cost (e.g., as of 2007, materials cost in SiC power devices accounted for 75% of the total to be contrasted with Si technology in which materials cost is less than 10%). In addition to the power semiconductor devices, there is a growing demand for devices made from a thin layer of SiC on a substrate to enable lower-cost development of microsystems for harsh environment power applications.

Applications generally desire that the SiC be high quality material not only for the power semiconductor devices but also for the power generation devices. For example, photon-enhanced thermionic energy converters generally need a low-defect single-crystal cathode to reduce recombination and increase the conversion efficiency.

Devices and methods that address the above problems are described herein. By using wafer bonding of a hydrogen-implanted wafer, the implanted hydrogen forms a buried plane of micro-cavities parallel to the bonding interface at the ion penetration depth. At high temperatures (>600° C.), the wafer splits along this plane and the top portion of the SiC can be easily removed, leaving behind a thin single-crystal SiC film layer bonded to the substrate. SiC smart-cut has been demonstrated with the direct (fusion) bonding technique, which typically requires extremely smooth surfaces (roughness <2Å root-mean-squared (RMS)) on both wafers to obtain a high fabrication yield. Since polishing SiC is extremely difficult, in some embodiments, the SiC wafer is thermally oxidized prior to the hydrogen implantation, and the oxide layer is polished after implantation to get a smooth surface.

To increase the bonding strength, the wafer stack may be annealed before the wafer splitting. Premature SiC splitting during anneal can be avoided if the temperature is lower than 600° C. However, in some embodiments, the wafer stack is annealed for as long as 24 hours at such temperatures to ensure that the bond strength is sufficient and the SiC is transferred onto the oxidized silicon substrate as a continuous layer rather than multiple SiC flakes. In some embodiments, plasma activation is used to achieve high bonding strength with shorter annealing times at lower temperatures.

As described herein, a use of Spin-on-glass (SoG) as an adhesion layer makes it possible in some examples to relax both the roughness and annealing requirements. Examples described herein utilize multiple times thin film layer transfer of a SiC smart-cut using SoG as an adhesion layer. With this technique, SiC smart-cut allows high fabrication yield even for materials with surface roughness as high as, for example, 7.5-12.5 Å RMS, significantly lowering costs associated with the SiCOI substrate.

Reference will be made to certain embodiments, examples of which are illustrated in the accompanying drawings. While the underlying principles will be described in conjunction with the embodiments, it will be understood that it is not intended to limit the scope of claims to these particular embodiments alone. On the contrary, the claims are intended to cover alternatives, modifications and equivalents that are within the scope of the claims.

Moreover, in the following description, numerous specific details are set forth to provide a thorough understanding of the underlying principles. However, it will be apparent to one of ordinary skill in the art that the underlying principles may be practiced without these particular details. In other instances, methods, procedures, and components that are well-known to those of ordinary skill in the art are not described in detail to avoid obscuring aspects of the underlying principles.

It will also be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer, without departing from the scope of the claims. The first layer and the second layer are both layers, but they are not the same layer.

The terminology used in the description of the embodiments herein is for the purpose of describing particular embodiments only and is not intended to limiting of the scope of claims. As used in the description and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, “on” is used to describe relative locations of a first element and a second element and a direct contact between the first element and the second element. For example, when the first element is positioned on the second element, the first element is positioned above the second element in a particular orientation and the first element is in contact with the second element.

As used herein, “over” is used to describe relative locations of a third element and a fourth element. For example, when the third element is positioned over the fourth element, the third element is positioned above the fourth element in a particular orientation. However, the term “over” does not necessarily require a direct contact between the third element and the fourth element. For example, when the third element is positioned over the fourth element, in some embodiments, one or more elements are positioned between the third element and the fourth element. Unless explicitly stated otherwise, some embodiments in which the third element is positioned over the fourth element include embodiments in which the third element is positioned on the fourth element.

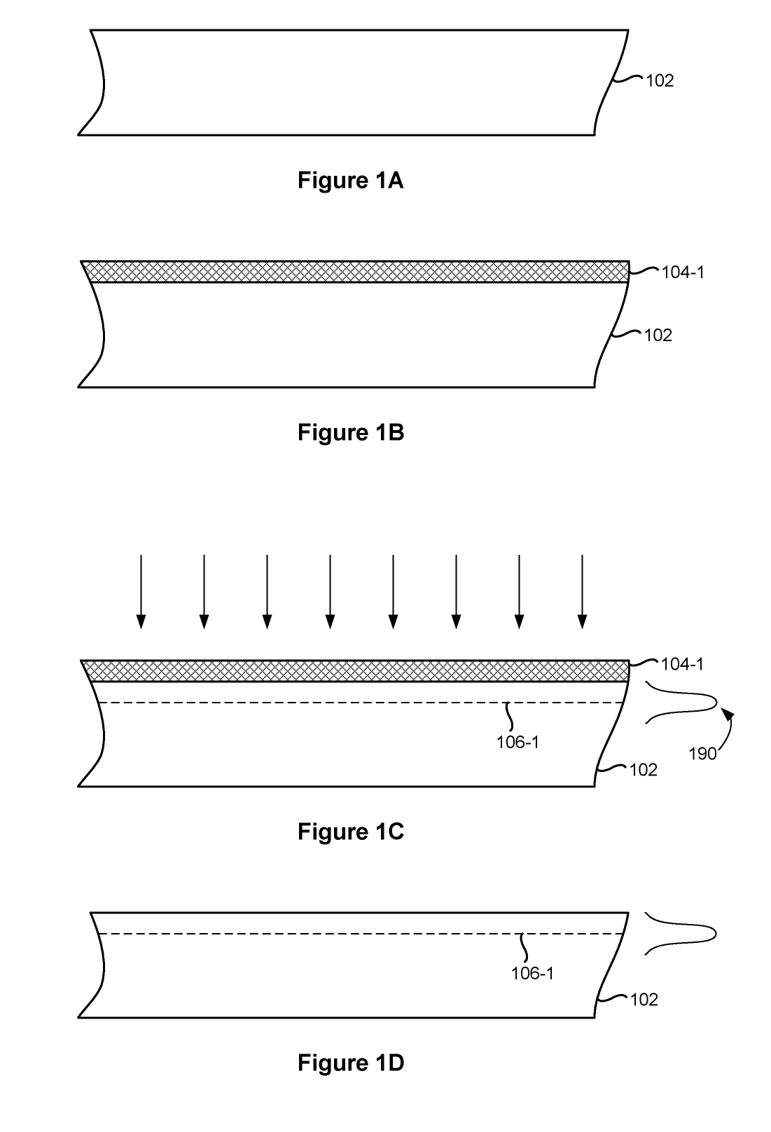

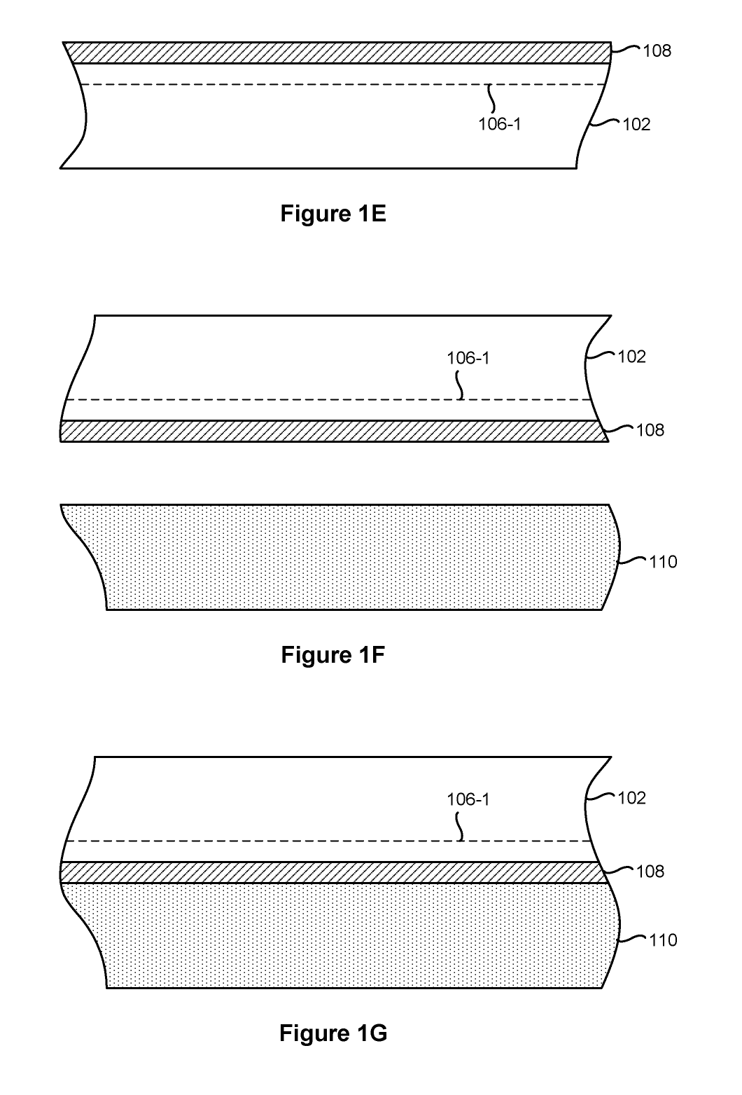

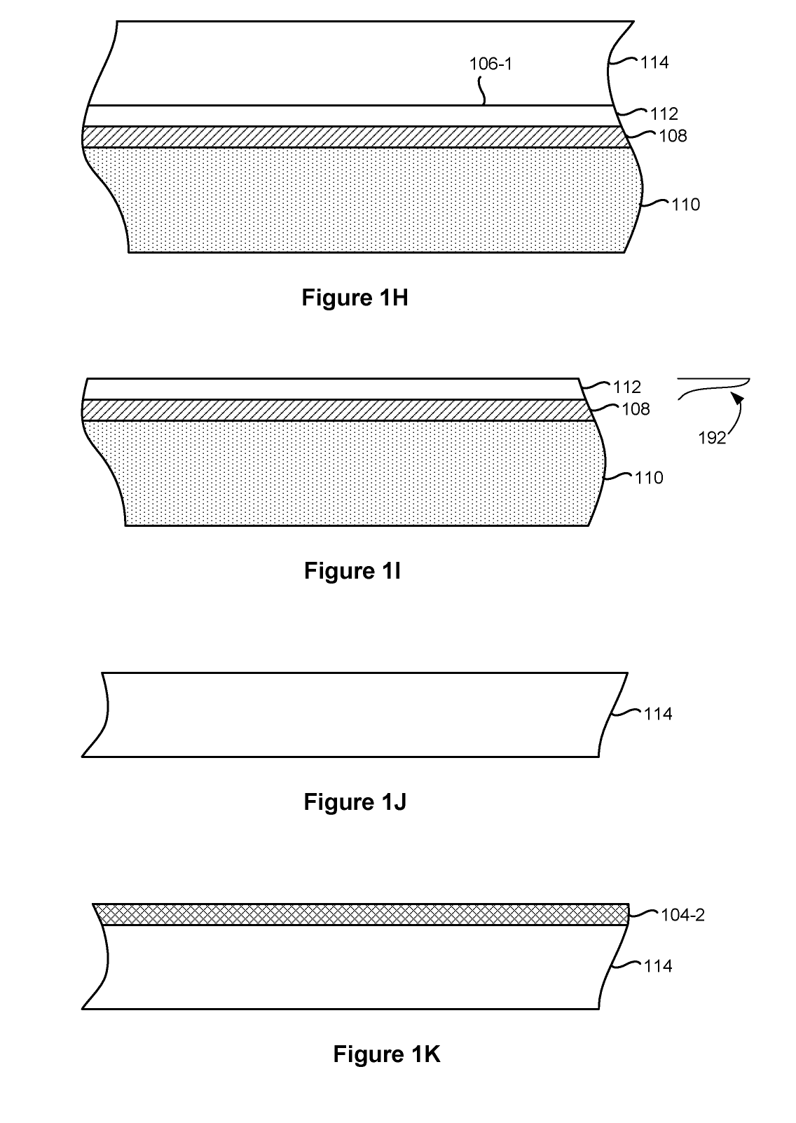

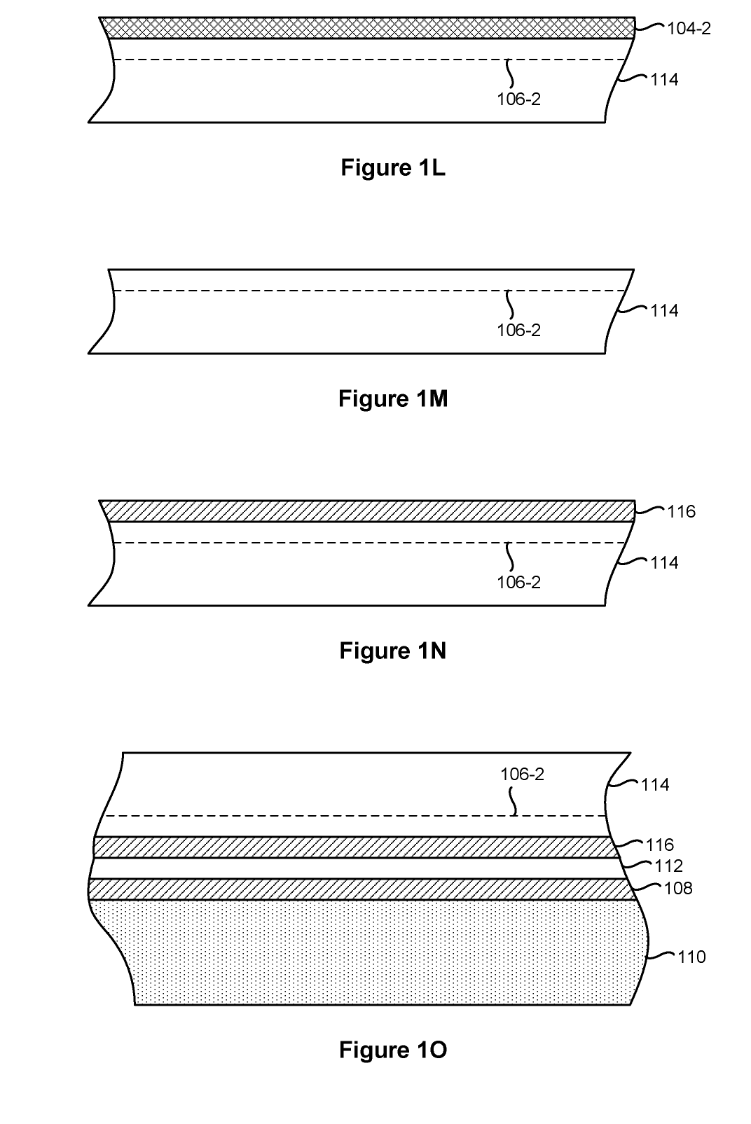

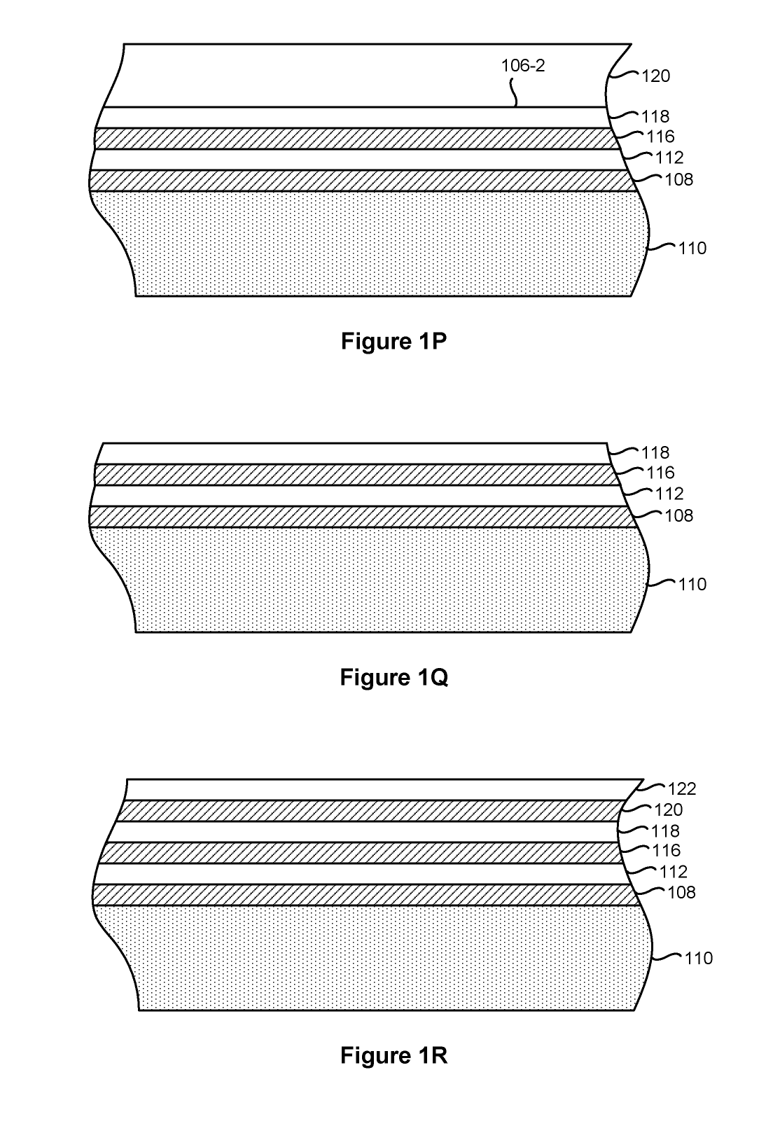

FIGS. 1A-1E are partial cross-sectional views of a silicon carbide wafer in accordance with some embodiments.

FIG. 1A is a partial cross-sectional view of a silicon carbide wafer 102.

FIG. 1B illustrates that an oxide layer 104-1 is formed on the silicon carbide wafer 102. In some embodiments, the oxide layer 104-1 is a low temperature oxide (e.g., silicon dioxide) deposited by using chemical vapor deposition. In some embodiments, the oxide layer 104-1 is silicon dioxide deposited by using plasma enhanced chemical vapor deposition. In some embodiments, the oxide layer 104-1 is formed by oxidizing a layer of the silicon carbide wafer 102.

FIG. 1C illustrates implantation of protons into the silicon carbide wafer 102. Shown on the right hand side of the silicon carbide wafer 102 is a prophetic example of a depth profile 190 of a proton (or hydrogen) concentration in the silicon carbide wafer 102. A region 106-1 with a high concentration of protons defines a plane that is substantially parallel to a top surface of the silicon carbide wafer 102 (e.g., the surface that faces the oxide layer 104-1). In some embodiments, an angle between the plane defined by the region 106-1 and the top surface of the silicon carbide wafer 102 is 30° or less. In some embodiments, the angle between the plane defined by the region 106-1 and the top surface of the silicon carbide wafer 102 is 20° or less. In some embodiments, the angle between the plane defined by the region 106-1 and the top surface of the silicon carbide wafer 102 is 15° or less. In some embodiments, the angle between the plane defined by the region 106-1 and the top surface of the silicon carbide wafer 102 is 10° or less. In some embodiments, the angle between the plane defined by the region 106-1 and the top surface of the silicon carbide wafer 102 is 5° or less.

FIG. 1D illustrates that, in some embodiments, the oxide layer 104-1 is removed.

FIG. 1E illustrates that a layer 108 of spin-on-glass is applied on the silicon carbide wafer 102.

FIGS. 1F-1I are partial cross-sectional views of a semiconductor substrate in accordance with some embodiments.

FIG. 1F illustrates that the silicon carbide wafer 102 is placed over the semiconductor substrate 110 while the layer 108 of spin-on-glass faces the semiconductor substrate 110.

FIG. 1G illustrates that the silicon carbide wafer 102 is pressed against the semiconductor substrate 110 so that the layer 108 of spin-on-glass comes in contact with the semiconductor substrate 110. The layer 108 of spin-on-glass is bonded to the semiconductor substrate 102. In some embodiments, the layer 108 of spin-on-glass is bonded to the semiconductor substrate 102 using low temperature annealing (e.g., annealing at a temperature lower than 600° C., such as 599.9° C., 599° C., 595° C., 590° C., 580° C., 575° C., 550° C., 500° C., 450° C., 400° C., 350° C., 300° C., 250° C., 200° C., 150° C., and 100° C.).

FIG. 1H illustrates that the silicon carbide wafer 102 is heated to initiate splitting of the silicon carbide wafer 102. As a result of splitting, the silicon carbide wafer 102 splits into a layer 112 of silicon carbide and a remaining portion 114 of the silicon carbide wafer.

FIG. 11 illustrates that the remaining portion 114 of the silicon carbide wafer is removed. Shown on the right hand side of the layer 112 of silicon carbide is a prophetic example of a depth profile 192 of a proton (or hydrogen) concentration in the layer 112 of silicon carbide. As shown in FIG. 11, a concentration of protons near a bottom surface (e.g., a surface that faces the semiconductor substrate 110) of the layer 112 of silicon carbide is lower than a concentration of protons near a top surface (e.g., a surface that is opposite to the bottom surface of the semiconductor substrate 110) of the layer 112 of silicon carbide.

FIGS. 1J-1N are partial cross-sectional views of a silicon carbide wafer in accordance with some embodiments.

FIG. 1J illustrates the remaining portion 114 of the silicon carbide wafer. In some embodiments, a surface of the remaining portion 114 (e.g., a surface that was formed by splitting the silicon carbide wafer 102) is polished (e.g., by using chemical-mechanical polishing).

FIG. 1K illustrates that an oxide layer 104-2 is formed on the remaining portion 114 of the silicon carbide wafer. The oxide layer 104-2 is similar to the oxide layer 104-1 described above with respect to FIG. 1B. For brevity, detailed description of the oxide layer 104-2 is omitted.

FIG. 1L illustrates that the remaining portion 114 of the silicon carbide wafer is implanted with protons. A region 106-2 with a high concentration of protons defines a plane that is substantially parallel to a top surface of the remaining portion 114 of the silicon carbide (e.g., the surface that faces the oxide layer 104-2).

FIG. 1M illustrates that, in some embodiments, the oxide layer 104-2 is removed.

FIG. 1N illustrates that a layer 116 of spin-on-glass is applied on the remaining portion 114 of the silicon carbide wafer.

FIGS. 1O-1R are partial cross-sectional views of a semiconductor substrate in accordance with some embodiments.

FIG. 1O illustrates that the remaining portion 114 of the silicon carbide wafer with the layer 116 of spin-on-glass is placed on the layer 112 of silicon carbide described above with respect to FIG. 1I.

FIG. 1P illustrates that the remaining portion 114 of the silicon carbide wafer is heated to initiate splitting of the remaining portion 114 of the silicon carbide wafer. As a result of splitting, the remaining portion 114 of the silicon carbide wafer splits into a layer 118 of silicon carbide and a second remaining portion 120 of the silicon carbide wafer.

FIG. 1Q illustrates that the second remaining portion 120 is removed.

In some embodiments, some of the steps described above are repeated to place additional layers of silicon carbide. For example, the steps illustrated in FIGS. 1J-1Q are repeated over a stack of silicon carbide layers. FIG. 1R illustrates a stack of three layers of silicon carbide. The three layers of silicon carbide are interspersed with layers of spin-on-glass. For example, in some embodiments, a layer of spin-on-glass is located between any two adjacent layers of silicon carbide. In some embodiments, a layer of silicon carbide is located between any two adjacent layers of spin-on-glass. In some embodiments, the stack of silicon carbide layers includes five or more layers of silicon carbide.

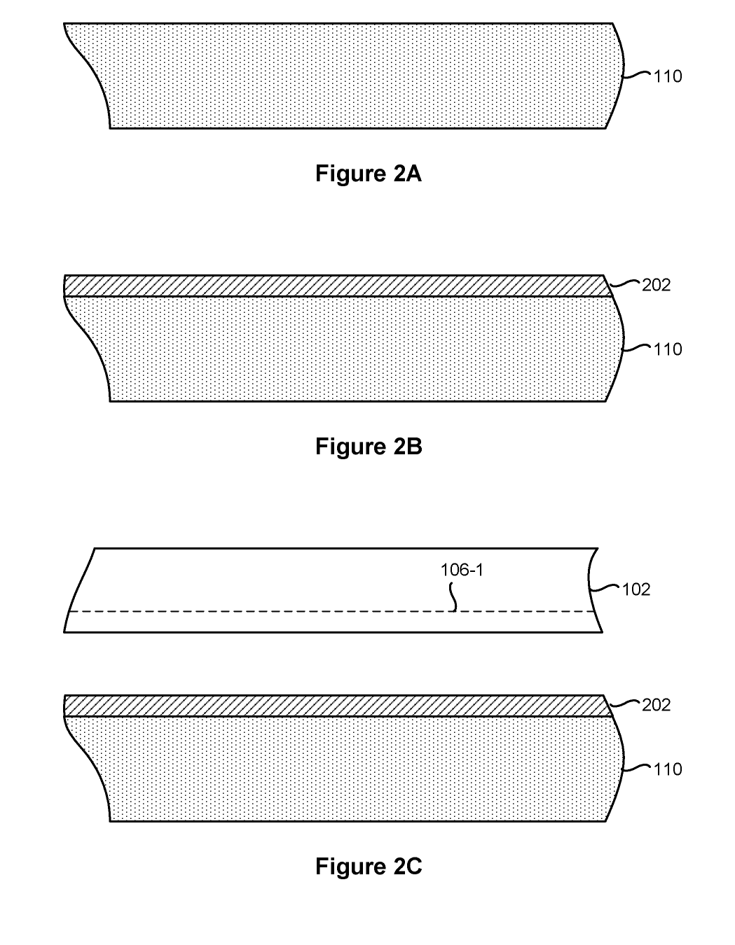

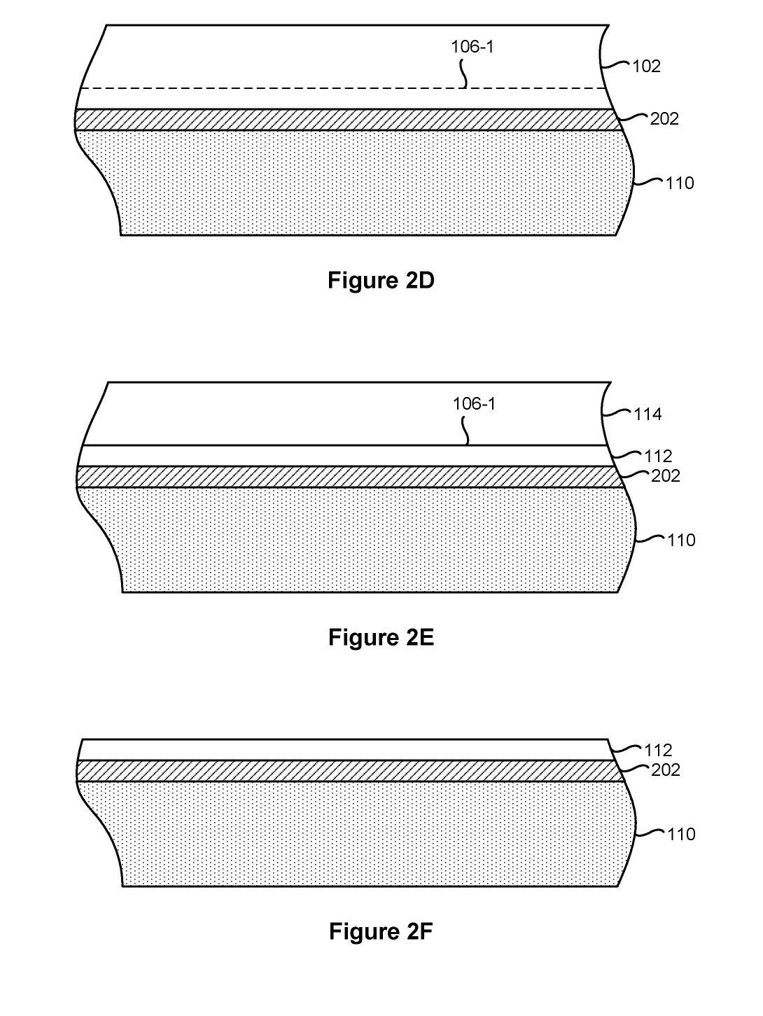

FIGS. 2A-2F are partial cross-sectional views of a semiconductor substrate in accordance with some embodiments.

FIG. 2A illustrates a semiconductor substrate 110.

FIG. 2B illustrates that a layer 202 of spin-on-glass is applied on the semiconductor substrate 110.

FIG. 2C illustrates that a silicon carbide wafer 102 implanted with protons is placed over the semiconductor substrate 110. In FIG. 2C, a surface adjacent to the proton implanted region 106-1 faces the semiconductor substrate 110, and the layer 202 of spin-on-glass faces the silicon carbide wafer 102.

FIG. 2D illustrates that the silicon carbide wafer 102 is pressed on the layer 202 of spin-on-glass. The silicon carbide wafer 102 is bonded to the layer 202 of spin-on-glass. In some embodiments, the silicon carbide wafer 102 is bonded to the layer 202 of spin-on-glass using low temperature annealing.

FIG. 2E illustrates that the silicon carbide wafer 102 is heated to initiate splitting of the silicon carbide wafer 102. As a result of splitting, the silicon carbide wafer 102 splits into a layer 112 of silicon carbide and a remaining portion 114 of the silicon carbide wafer.

FIG. 2F illustrates that the remaining portion 114 of the silicon carbide wafer is removed.

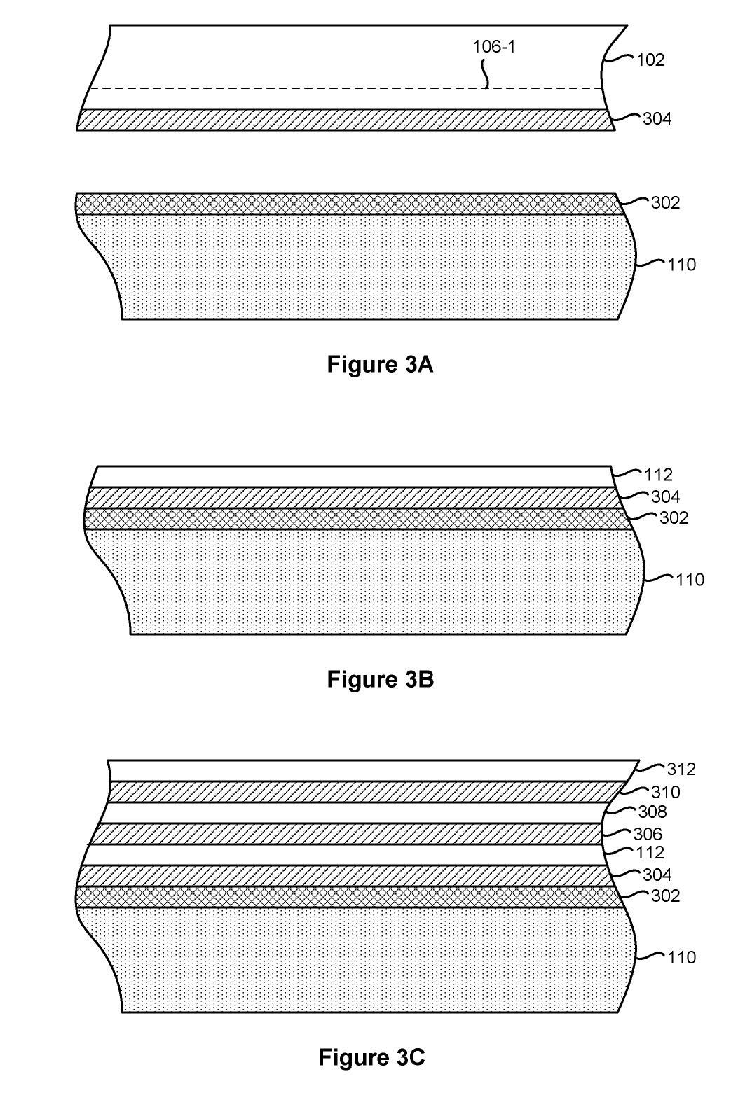

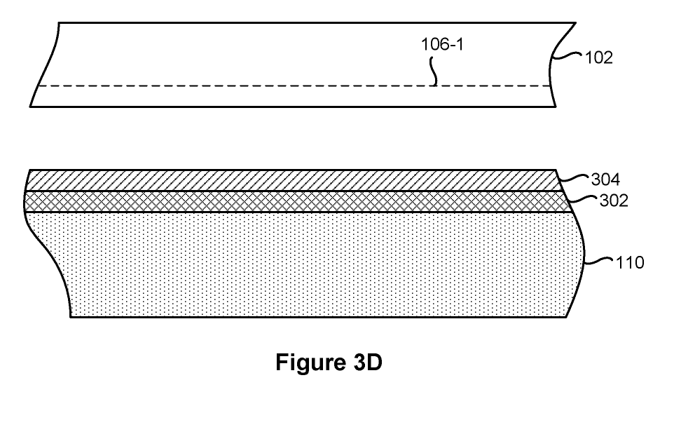

FIGS. 3A-3D are partial cross-sectional views of a semiconductor substrate in accordance with some embodiments. FIGS. 3A-3D illustrate that a layer of spin-on-glass need not be in direct contact with the semiconductor substrate (e.g., one or more layers of different materials are placed between the layer of spin-on-glass and the semiconductor substrate).

FIG. 3A illustrates that an oxide layer 302 (e.g., a layer of silicon dioxide) is placed on the semiconductor substrate 110. The silicon carbide wafer 102 implanted with protons has a layer 304 of spin-on-glass applied thereon. The silicon carbide wafer 102 is placed over the semiconductor substrate 110.

FIG. 3B illustrates that the layer 304 of spin-on-glass is bonded to the oxide layer 302 (e.g., using low temperature annealing) and the silicon carbide wafer 102 is heated to initiate splitting and a portion of the silicon carbide wafer 102 is removed, leaving a layer 112 of silicon carbide over the semiconductor substrate 110.

FIG. 3C illustrates that the bonding, heating, and removing steps are repeated to form a stack of silicon carbide layers. The silicon carbide layers 112, 308, and 312 are interspersed with layers 306 and 310 of spin-on-glass. In some embodiments, a layer of spin-on-glass is located between any two adjacent layers of silicon carbide. In some embodiments, a layer of silicon carbide is located between any two adjacent layers of spin-on-glass.

FIG. 3D illustrates that, in some embodiments, the layer 304 of spin-on-glass is applied on the oxide layer 302 before the silicon carbide wafer 102 comes in contact with the layer 304 of spin-on-glass.

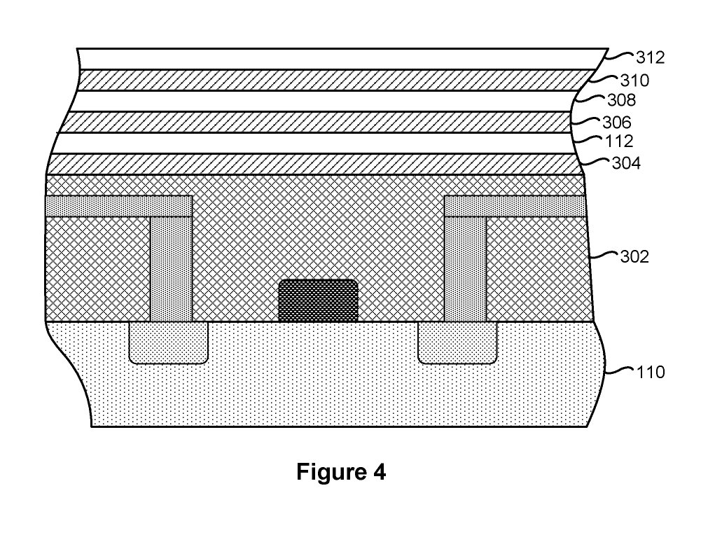

FIG. 4 is a partial cross-sectional view of a semiconductor device in accordance with some embodiments.

In FIG. 4, a transistor (e.g., a MOSFET) is formed using the semiconductor substrate 110. In some embodiments, the transistor is covered with an oxide layer. FIG. 4 also shows that a stack of silicon carbide layers (e.g., 112, 308, and 312) is formed over the transistor.

In accordance with some embodiments, a semiconductor device includes a semiconductor substrate; a first layer of spin-on-glass positioned over the semiconductor substrate; a first layer of silicon carbide positioned over the first layer of spin-on-glass; a second layer of spin-on-glass positioned over the first layer of silicon carbide; and a second layer of silicon carbide positioned over the second layer of spin-on-glass. For example, the semiconductor device in FIG. 1Q includes the semiconductor substrate 110, the first layer of spin-on-glass 108 on the semiconductor substrate 110, the first layer of silicon carbide 112 on the first layer of spin-on-glass 108, the second layer of spin-on-glass 116 on the first layer of silicon carbide 112, and the second layer of silicon carbide 118 on the second layer of spin-on-glass 116.

In some embodiments, the semiconductor device also includes a third layer of spin-on-glass positioned over the second layer of silicon carbide; and a third layer of silicon carbide positioned over the third layer of spin-on-glass. For example, the semiconductor device in FIG. 1R includes the third layer of spin-on-glass 120 on the second layer of silicon carbide 118, and the third layer of silicon carbide 122 on the third layer of spin-on-glass 120.

In some embodiments, a respective layer of silicon carbide has a concentration of protons in the respective layer of silicon carbide near a bottom surface of the respective layer of silicon carbide that is lower than a concentration of protons in the respective layer of silicon carbide near a top surface of the respective layer of silicon carbide, the bottom surface of the respective layer of silicon carbide being a planar surface facing the semiconductor substrate and the top surface of the respective layer of silicon carbide being a planar surface that is opposite to the bottom surface of the respective layer of silicon carbide. For example, as shown in FIG. 11, a concentration of protons near the bottom surface is lower than a concentration of protons near the top surface.

In some embodiments, the second layer of silicon carbide has a concentration of protons in the second layer of silicon carbide near a bottom surface of the second layer of silicon carbide that is lower than a concentration of protons in the second layer of silicon carbide near a top surface of the second layer of silicon carbide, the bottom surface of the second layer of silicon carbide being a planar surface facing the semiconductor substrate and the top surface of the second layer of silicon carbide being a planar surface that is opposite to the bottom surface of the second layer of silicon carbide. For example, in FIG. 1Q, the second layer of silicon carbide 118 has a concentration of protons near the bottom surface that is lower than a concentration of protons near the top surface.

In some embodiments, the third layer of silicon carbide has a concentration of protons in the third layer of silicon carbide near a bottom surface of the third layer of silicon carbide that is lower than a concentration of protons in the third layer of silicon carbide near a top surface of the third layer of silicon carbide, the bottom surface of the third layer of silicon carbide being a planar surface facing the semiconductor substrate and the top surface of the third layer of silicon carbide being a planar surface that is opposite to the bottom surface of the third layer of silicon carbide. For example, in FIG. 1R, the third layer of silicon carbide 122 has a concentration of protons near the bottom surface that is lower than a concentration of protons near the top surface.

In some embodiments, the semiconductor device includes an oxide layer positioned on the semiconductor substrate, and the first layer of spin-on-glass is positioned on the oxide layer on the semiconductor substrate. For example, in FIG. 3B, the first oxide layer 304 is positioned on the semiconductor substrate, and the first layer 304 of spin-on-glass is positioned on the first oxide layer 304.

In some embodiments, the semiconductor device includes a transistor, and the first layer of spin-on-glass is positioned over the transistor. For example, in FIG. 4, the semiconductor device includes a transistor (e.g., MOSFET) and the first layer 304 of spin-on-glass is positioned above the transistor.

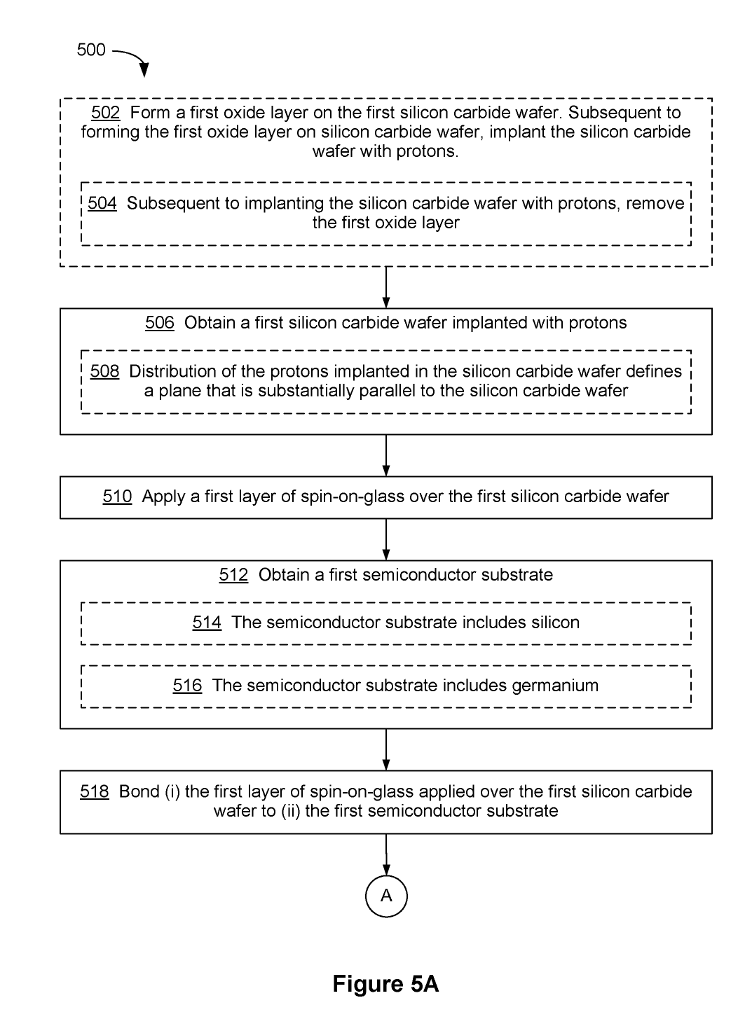

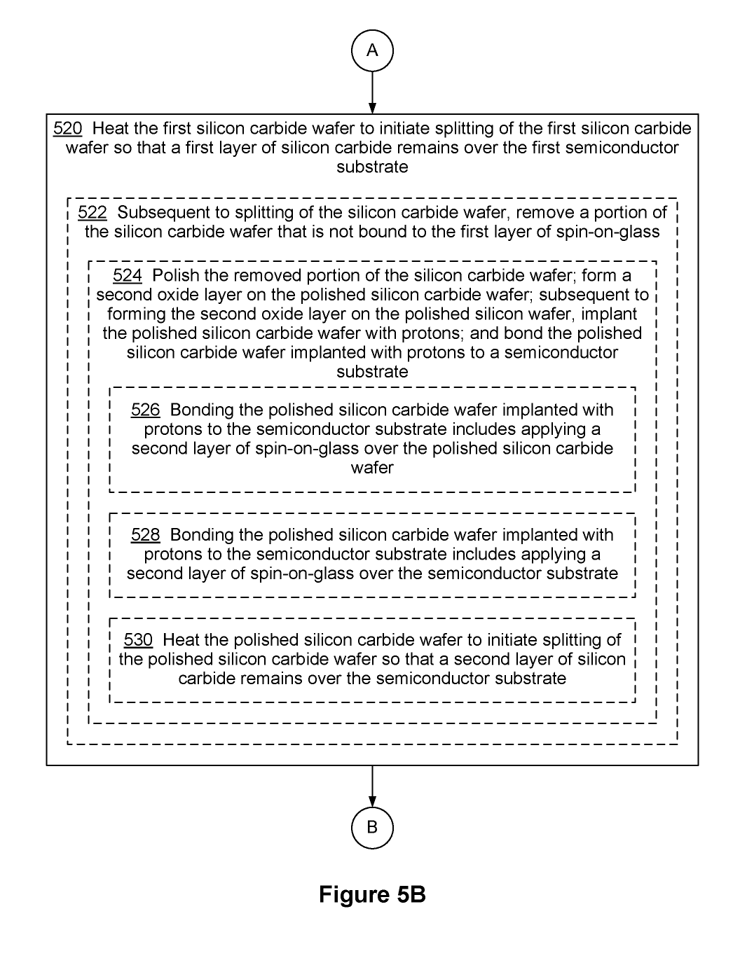

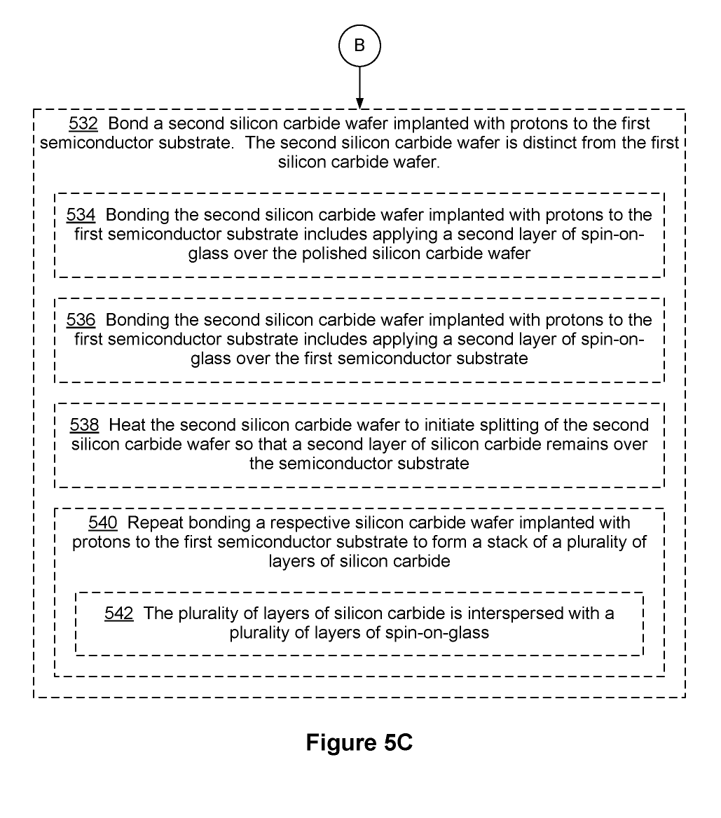

FIGS. 5A-5C are flow diagrams illustrating a method 500 of transferring a layer of silicon carbide onto a semiconductor substrate in accordance with some embodiments.

In some embodiments, the method 500 includes (502), prior to the bonding, forming a first oxide layer on the first silicon carbide wafer (e.g., in FIG. 1B, the first oxide layer 104-1 is formed on the silicon carbide wafer 102); and, subsequent to forming the first oxide layer on silicon carbide wafer, implanting the silicon carbide wafer with protons (e.g., in FIG. 1C, the silicon carbide wafer 102 is implanted with protons). In some embodiments, the first oxide layer is formed by oxidation of silicon carbide in the silicon carbide wafer. In some embodiments, the first oxide layer is formed by using a chemical vapor deposition process. In some embodiments, the first oxide layer is a low temperature oxide.

In some embodiments, the method 500 includes (504), subsequent to implanting the silicon carbide wafer with protons, removing the first oxide layer (e.g., in FIG. 1D, the first oxide layer 104-1 shown in FIG. 1C is removed). For example, in some embodiments, the first oxide layer is removed using a wet etch process (using an etchant, such as buffered hydrofluoric acid). Alternatively or additionally, plasma etching (e.g., using trifluoromethane) and/or chemical-mechanical-polishing are used to remove the first oxide layer.

The method 500 includes (506) obtaining a first silicon carbide wafer implanted with protons (e.g., silicon carbide wafer 102 in FIG. 1D).

In some embodiments, distribution of the protons implanted in the silicon carbide wafer defines (508) a plane that is substantially parallel to the silicon carbide wafer. For example, as illustrated in FIG. 1D, the plane defined by the region 106-1 with a high concentration of protons is substantially parallel to the silicon carbide wafer 102. As used herein, the plane is deemed to be substantially parallel to the silicon carbide wafer when an angle between the plane defined by the region 106-1 and the top surface of the silicon carbide wafer 102 is 30° or less. In some embodiments, the plane is deemed to be substantially parallel to the silicon carbide wafer when the angle between the plane defined by the region 106-1 and the top surface of the silicon carbide wafer 102 is 20° or less. In some embodiments, the plane is deemed to be substantially parallel to the silicon carbide wafer when the angle between the plane defined by the region 106-1 and the top surface of the silicon carbide wafer 102 is 15° or less. In some embodiments, the plane is deemed to be substantially parallel to the silicon carbide wafer when the angle between the plane defined by the region 106-1 and the top surface of the silicon carbide wafer 102 is 10° or less. In some embodiments, the plane is deemed to be substantially parallel to the silicon carbide wafer when the angle between the plane defined by the region 106-1 and the top surface of the silicon carbide wafer 102 is 5° or less.

The method 500 includes (510) applying a first layer of spin-on-glass over the first silicon carbide wafer (e.g., the first layer 108 of spin-on-glass is applied on the silicon carbide wafer 102 in FIG. 1E).

The method 500 includes (512) obtaining a first semiconductor substrate (e.g., the semiconductor substrate 110 in FIG. 1F).

In some embodiments, the semiconductor substrate includes (514) silicon. In some embodiments, the semiconductor substrate is a silicon substrate.

In some embodiments, the semiconductor substrate includes (516) germanium. In some embodiments, the semiconductor substrate is a germanium substrate.

The method 500 includes (518) bonding (i) the first layer of spin-on-glass applied over the first silicon carbide wafer to (ii) the first semiconductor substrate. For example, in FIG. 1G, the first layer 108 of spin-on-glass is bonded to the semiconductor substrate 110. In some embodiments, bonding the first layer of spin-on-glass applied over the first silicon carbide wafer to the first semiconductor substrate includes heating the first layer 108 of spin-on-glass and/or the semiconductor substrate 110 to a temperature that does not initiate splitting of the silicon carbide wafer (e.g., less than 600° C., such as 250° C., 400° C., or 500° C.).

The method 500 includes (520) heating the first silicon carbide wafer to initiate splitting of the first silicon carbide wafer so that a first layer of silicon carbide remains over the first semiconductor substrate. For example, in FIG. 1H, the silicon carbide wafer is split into two parts: a layer 112 of silicon carbide and a remaining portion 114 of the silicon carbide wafer. In some embodiments, heating the first silicon carbide wafer to initiate splitting of the first silicon carbide wafer includes heating the first silicon carbide wafer to a temperature higher than 600° C. (e.g., 800° C.).

In some embodiments, the method 500 includes (522), subsequent to splitting of the silicon carbide wafer, removing a portion of the silicon carbide wafer that is not bound to the first layer of spin-on-glass. For example, in FIG. 11, the remaining portion of the silicon carbide wafer 114 is removed.

In some embodiments, the method 500 includes (524) polishing the removed portion of the silicon carbide wafer (e.g., the removed portion 114 of the silicon carbide wafer in FIG. 1J is polished, for example, using chemical-mechanical-polishing); forming a second oxide layer on the polished silicon carbide wafer (e.g., the second oxide layer 104-2 in FIG. 1K); subsequent to forming the second oxide layer on the polished silicon wafer, implanting the polished silicon carbide wafer with protons (e.g., in FIG. 1L, protons are implanted); and bonding the polished silicon carbide wafer implanted with protons to a semiconductor substrate (e.g., using a layer 104-2 of spin-on-glass as shown in FIG. 1N). In some embodiments, the semiconductor substrate is the first semiconductor substrate. For example, the polished silicon carbide wafer is bonded with the same first semiconductor substrate. In some embodiments, bonding the polished silicon carbide wafer with the same first semiconductor substrate includes forming a stack of multiple layers of silicon carbide on the first semiconductor substrate. For example, FIG. 1O shows the semiconductor substrate 110 with multiple layers of silicon carbide (e.g., a first layer of silicon carbide 112 and the polished silicon carbide wafer 114). In some embodiments, the polished silicon carbide wafer is bonded at a location on the first silicon carbide wafer that does not overlap with the first layer of silicon carbide placed over the first semiconductor substrate. In some embodiments, the semiconductor substrate is a second semiconductor substrate that is distinct and separate from the first semiconductor substrate. For example, the polished silicon carbide wafer is bonded with a different semiconductor substrate. This allows reuse of the polished silicon carbide wafer, thereby reducing the cost in placing silicon carbide layers on semiconductor substrates.

In some embodiments, the method 500 includes, subsequent to implanting the polished silicon carbide wafer with protons, removing the second oxide layer (e.g., in FIG. 1M, the layer 104-2 of spin-on-glass shown in FIG. 1L is removed).

In some embodiments, bonding the polished silicon carbide wafer implanted with protons to the semiconductor substrate includes (526) applying a second layer of spin-on-glass over the polished silicon carbide wafer (e.g., the second layer 116 of spin-on-glass is applied over the polished silicon carbide wafer 114 in FIG. 1N).

In some embodiments, bonding the polished silicon carbide wafer implanted with protons to the semiconductor substrate includes (528) applying a second layer of spin-on-glass over the semiconductor substrate. In some embodiments, a layer of spin-on-glass is applied over the semiconductor substrate (e.g., over the first layer 112 of silicon carbide in FIG. 1I) in addition to applying a layer of spin-on-glass over the polished silicon carbide wafer. In some embodiments, a layer of spin-on-glass is applied over the semiconductor substrate (e.g., over the first layer 112 of silicon carbide in FIG. 1I) without applying a layer of spin-on-glass over the polished silicon carbide wafer.

In some embodiments, the method 500 includes (530) heating the polished silicon carbide wafer to initiate splitting of the polished silicon carbide wafer so that a second layer of silicon carbide remains over the semiconductor substrate. For example, in FIG. 1P, the polished silicon carbide wafer 114 is heated to initiate splitting of the polished silicon carbide wafer into the second layer 118 of silicon carbide and the second remaining portion 120 of the silicon carbide wafer. In some embodiments, the second layer of silicon carbide remains on the second layer of spin-on-glass.

In some embodiments, the method 500 includes (532) bonding a second silicon carbide wafer implanted with protons to the first semiconductor substrate, and the second silicon carbide wafer is distinct from the first silicon carbide wafer. In some embodiments, the second silicon carbide wafer is the polished silicon carbide wafer. In some embodiments, the second silicon carbide wafer is a silicon carbide wafer that is distinct and separate from the polished silicon carbide wafer.

In some embodiments, bonding the second silicon carbide wafer implanted with protons to the first semiconductor substrate includes (534) applying a second layer of spin-on-glass over the polished silicon carbide wafer (e.g., the second layer 116 of spin-on-glass is applied over the polished silicon carbide wafer 114 in FIG. 1N).

In some embodiments, bonding the second silicon carbide wafer implanted with protons to the first semiconductor substrate includes (536) applying a second layer of spin-on-glass over the first semiconductor substrate (e.g., over the first layer 112 of silicon carbide in FIG. 1I.

In some embodiments, the method 500 includes (538) heating the second silicon carbide wafer to initiate splitting of the second silicon carbide wafer so that a second layer of silicon carbide remains over the semiconductor substrate. For example, in FIG. 1P, the polished silicon carbide wafer 114 is heated to initiate splitting of the polished silicon carbide wafer into the second layer 118 of silicon carbide and the second remaining portion 120 of the silicon carbide wafer. In some embodiments, the second layer of silicon carbide remains on the second layer of spin-on-glass.

In some embodiments, the method 500 includes (540) repeating bonding a respective silicon carbide wafer implanted with protons to the first semiconductor substrate to form a stack of a plurality of layers of silicon carbide. For example, the semiconductor substrate 110 in FIG. 1R has three layers of silicon carbide (e.g., 112, 118, and 122) over the semiconductor substrate 110. In some embodiments, the stack of a plurality of layers of silicon carbide has a thickness of at least 5 microns. In some embodiments, the stack of a plurality of layers of silicon carbide has a thickness of at least 10 microns. In some embodiments, the stack of a plurality of layers of silicon carbide has a thickness of at least 15 microns. In some embodiments, the stack of a plurality of layers of silicon carbide has a thickness of at least 25 microns. In some embodiments, the stack of a plurality of layers of silicon carbide has a thickness of at least 50 microns.

In some embodiments, the plurality of layers of silicon carbide is interspersed (542) with a plurality of layers of spin-on-glass. For example, in FIG. 1R, a layer of spin-on-glass is located between any two adjacent layers of silicon carbide (e.g., the layer 116 of spin-on-glass is located between the layers 112 and 118 of silicon carbide and the layer 120 of spin-on-glass is located between the layers 118 and 122 of silicon carbide).

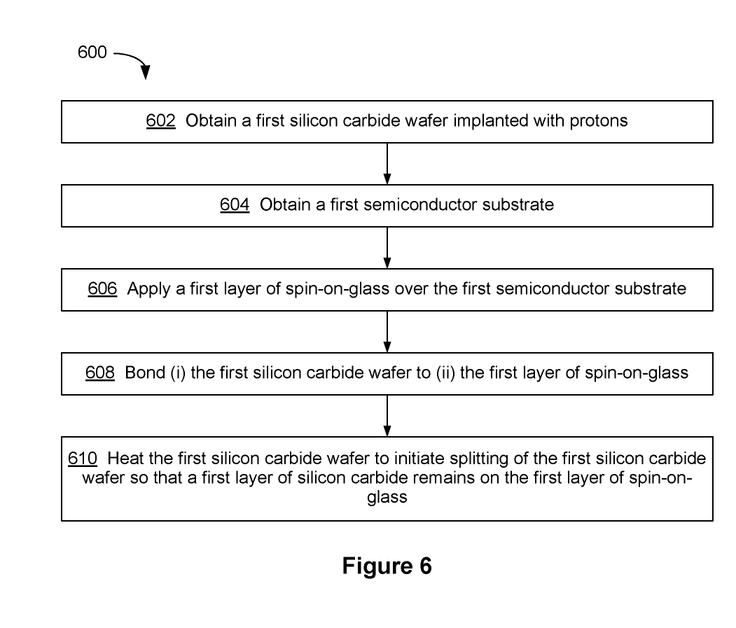

FIG. 6 is a flow diagram illustrating a method 600 of transferring a layer of silicon carbide onto a semiconductor substrate in accordance with some embodiments.

The method 600 includes (602) obtaining a first silicon carbide wafer implanted with protons (e.g., the silicon carbide wafer 102, FIG. 2C).

The method 600 includes (604) obtaining a first semiconductor substrate (e.g., the semiconductor substrate 110 in FIG. 2A).

The method 600 includes (606) applying a first layer of spin-on-glass over the first semiconductor substrate (e.g., a layer 202 of spin-on-glass on the semiconductor substrate 110 in FIG. 2B).

The method 600 includes (608) bonding (i) the first silicon carbide wafer to (ii) the first layer of spin-on-glass. For example, the silicon carbide wafer 102 is bonded to the layer 202 of spin-on-glass in FIG. 2D.

The method 600 includes (610) heating the first silicon carbide wafer to initiate splitting of the first silicon carbide wafer so that a first layer of silicon carbide remains on the first layer of spin-on-glass. For example, the silicon carbide wafer 102 in FIG. 2D is heated to initiate splitting of the silicon carbide wafer 102 and a layer 112 of silicon carbide remains on the layer 202 of spin-on-glass in FIG. 2E.

Some of the features described above with respect to the method 500 are applicable to the method 600. For example, the first semiconductor substrate in the method 600 includes silicon or germanium. For brevity, such details are not repeated herein.

In the methods 500 and 600, the illustrated sequence of steps is not intended to limit the scope of claims, unless a relative sequence of steps is explicitly recited. Thus, some of the steps can be performed in a sequence different from the sequence illustrated in FIGS. 5A-5C and 6. For example, in the method 600, applying a first layer of spin-on-glass over the first silicon carbide wafer may be performed before, after, or concurrently with, obtaining the first semiconductor substrate. In another example, in the method 600, obtaining a first silicon carbide wafer implanted with protons may be performed before, after, or concurrently with, obtaining the first semiconductor substrate.

### EXAMPLES

Examples of transfer of a single layer of SiC using SoG are described below. Following discussion of the single layer transfer, multiple-layer transfer procedures are described. Although the examples are described using transfer of a portion of a layer of material (e.g. at chip scale), in other examples, other sizes of material layers may be transferred, including a layer of a wafer (e.g. at wafer scale).

Some examples of SiC layer transfer include implantation of ions at a depth suitable for defining a layer to be transferred. For examples, ions were implanted into a SiC substrate at a depth of between 1-5 microns below the substrate surface. Other depths may be used in other examples. The depth of the ions (which may be defined as a depth of a peak ion concentration) generally defines a thickness of material that may be transferred. To protect the substrate surface during ion implantation, a protective layer (e.g. an oxide) was provided on the wafer surface. Following implantation, the substrate was diced into smaller sections (e.g. chips) in some examples.

A receiving substrate was prepared to receive the SiC layer from the SiC substrate. Examples of the receiving substrate include but are not limited to Si substrates, oxide substrates, or Si substrates having an oxide or other insulating layer. Generally, the ion implantation process tend to roughen the SiC substrate, or portions of the SiC substrate such that direct bonding of the SiC substrate to the receiving substrate (e.g. Si substrate) became difficult. Accordingly, a smoothing material is used. A smoothing material that provides a more planar surface was desired. Examples described herein utilized spin-on glass (SoG) as the smoothing material.

The SiC substrate (or diced portion(s) of the substrate) was then brought into contact with the receiving substrate through the smoothing material. The smoothing material was disposed on either the SiC substrate (or portions thereof), the receiving substrate, or both. The SiC substrate, smoothing material, receiving substrate stack was then be bonded together. Once bonded, the SiC substrate was cracked (also called herein split) at the location of the peak ion implant, leaving a transferred layer of SiC on the receiving substrate. Cracking may be initiated in a variety of ways, including heating of the substrate.

An example fabrication process flow of the single-crystal SiC smart-cut technique with SoG began with a commercial 3-inch p-type 4H-SiC wafer from Cree, Inc. (360-μm thickness, ˜1 Ohm□cm resistivity, 8° off-axis orientation). A 50 nm thick low temperature oxide (LTO) was deposited at 400° C. to act as a surface protection layer for wafer handling during the subsequent implantation. Since the commercial 3-inch p-type 4H-SiC wafer comes miscut with an 8° off-axis orientation, protons were implanted vertically to create an 8° angle between the ion beam and the c-axis of the single-crystal wafer to avoid channeling effects. A proton dosage of 1×10¹⁷ cm-2 was shown to be adequate for silicon carbide layer splitting and was therefore selected for this experiment. Since the location of the peak proton concentration is controlled by the implant energy, the implant energies of 200 and 400 keV were chosen to achieve peak hydrogen concentrations approximately 1.3 and 3.0 μm below the wafer surface.

The implanted 3-inch 4H-SiC wafer was then diced into approximately 1 cm square pieces. After the wet etch of LTO, a 1 cm² die of SiC and a Si (100) substrate with a 1.6 μm thick thermal oxide were cleaned in deionized (DI) water, followed by a reverse RCA cleaning to remove any contamination and to obtain hydrophilic surfaces. However, since the ion implantation increases the roughness of the SiC surface by about an order of magnitude (FIG. 2), a SiC die cannot easily be direct-bonded to a carrier wafer. Furthermore, polishing SiC to get a smooth surface is not trivial, and thermal oxidation is not an option for ion-implanted SiC wafers since the oxidation temperature is higher than the wafer splitting temperature. Therefore, rather than doing direct bonding, a flowable hydrogen-silsesquioxane (HSQ)-based inorganic SoG (Dow XR-1541) was used as an adhesion layer. This type of SoG was chosen for its ability to planarize the surface, facilitate an initial low temperature bond, and withstand the thermal stresses at high temperatures where layer splitting occurs (800-900° C.). In other examples, other SoG may be used.

A carrier wafer was coated with a 100-150 nm thick layer of SoG. The front SiC surface, through which ions had been implanted, was brought into contact with the SoG-coated carrier wafer. The two substrates were initially bonded together at room temperature with approximately 1 MPa pressure applied for 1 min. The substrates were then heated to 80° C. for 1 min, 150° C. for another 1 min, and finally 250° C. while maintaining the same pressure on a hot plate. The bonded sample was then transferred to a tube furnace for the SiC splitting. The temperature was slowly ramped to 900° C. at a rate of less than 10° C./min to avoid thermal shock, and then kept at this high temperature for 2 hrs to initiate the splitting along the plane of peak hydrogen concentration. As a result, a single-crystal 4H-SiC layer with a thickness of about 1.3 μm was successfully transferred onto the oxidized silicon substrate.

In some embodiments, the layer-transferred silicon carbide was annealed for 4 hrs at 1140° C. immediately after being split. This was found to reduce the stress and stress gradient in the layer-transferred silicon carbide.

Furthermore, a same silicon carbide wafer was used multiple times to provide layers of SiC for transfer to receiving substrates. In some embodiments, following transfer of one layer of SiC to a receiving substrate, the remaining SiC wafer (or substrate or die) may again be treated with ion implantation and utilized to provide another layer of SiC to another (or the same) receiving substrate. In some embodiments, the remaining SiC wafer (or substrate or die) was polished following removal of a layer of SiC to facilitate the bonding of the remaining substrate to a receiving substrate through a smoothing layer. In some cases, the remaining SiC wafer (or substrate or die) showed an average surface roughness of 25-50ÅRMS and a few micron-scale SiC flakes were found on the remaining SiC wafers (or substrates or dies). With minor polishing these SiC flakes can be removed and the remaining SiC wafer (or substrate or die) was reused to conduct another “smart-cut” layer transfer process using the process described herein. Any of a variety of polishing techniques may be used, including, but not limited to, chemical-mechanical polishing (CMP).

The foregoing description, for purpose of explanation, has been described with reference to specific examples and embodiments. However, the illustrative discussions above are not intended to be exhaustive or to limit the scope of claims to the precise forms disclosed. Many modifications and variations are possible in view of the above teachings. The embodiments were chosen and described in order to best explain the underlying principles and their practical applications, to thereby enable others skilled in the art to best utilize the underlying principles and various embodiments with various modifications as are suited to the particular use contemplated.

In addition, it is to be understood that some embodiments are described as stated in the following clauses:
1. A method, comprising:
obtaining a first silicon carbide wafer implanted with protons;
applying a first layer of spin-on-glass over the first silicon carbide wafer;
obtaining a first semiconductor substrate;
bonding (i) the first layer of spin-on-glass applied over the first silicon carbide wafer to (ii) the first semiconductor substrate; and
heating the first silicon carbide wafer to initiate splitting of the first silicon carbide wafer so that a first layer of silicon carbide remains over the first semiconductor substrate.
2. A method comprising:
obtaining a first silicon carbide wafer implanted with protons;
obtaining a first semiconductor substrate;
applying a first layer of spin-on-glass over the first semiconductor substrate;
bonding (i) the first silicon carbide wafer to (ii) the first layer of spin-on-glass; and
heating the first silicon carbide wafer to initiate splitting of the first silicon carbide wafer so that a first layer of silicon carbide remains on the first layer of spin-on-glass.
3. The method of clause 1 or 2, further comprising: prior to the bonding:
forming a first oxide layer on the first silicon carbide wafer; and,
subsequent to forming the first oxide layer on silicon carbide wafer, implanting the silicon carbide wafer with protons.
4. The method of clause 3, further comprising:
subsequent to implanting the silicon carbide wafer with protons, removing the first oxide layer.
5. The method of any of clauses 1-4, wherein distribution of the protons implanted in the silicon carbide wafer defines a plane that is substantially parallel to the silicon carbide wafer.
6. The method of any of clauses 1-5, further comprising:
subsequent to splitting of the silicon carbide wafer, removing a portion of the silicon carbide wafer that is not bound to the first layer of spin-on-glass.
7. The method of clause 6, further comprising:
polishing the removed portion of the silicon carbide wafer;
forming a second oxide layer on the polished silicon carbide wafer;
subsequent to forming the second oxide layer on the polished silicon wafer, implanting the polished silicon carbide wafer with protons; and
bonding the polished silicon carbide wafer implanted with protons to a semiconductor substrate.
8. The method of clause 7, wherein bonding the polished silicon carbide wafer implanted with protons to the semiconductor substrate includes applying a second layer of spin-on-glass over the polished silicon carbide wafer.
9. The method of clause 7, wherein bonding the polished silicon carbide wafer implanted with protons to the semiconductor substrate includes applying a second layer of spin-on-glass over the semiconductor substrate.
10. The method of any of clauses 7-9, further comprising:
heating the polished silicon carbide wafer to initiate splitting of the polished silicon carbide wafer so that a second layer of silicon carbide remains over the semiconductor substrate.
11. The method of any of clauses 1-6, including:
bonding a second silicon carbide wafer implanted with protons to the first semiconductor substrate, wherein the second silicon carbide wafer is distinct from the first silicon carbide wafer.
12. The method of clause 11, wherein bonding the second silicon carbide wafer implanted with protons to the first semiconductor substrate includes applying a second layer of spin-on-glass over the polished silicon carbide wafer.
13. The method of clause 11, wherein bonding the second silicon carbide wafer implanted with protons to the first semiconductor substrate includes applying a second layer of spin-on-glass over the first semiconductor substrate.
14. The method of any of clauses 11-13, further comprising:
heating the second silicon carbide wafer to initiate splitting of the second silicon carbide wafer so that a second layer of silicon carbide remains over the semiconductor substrate.
15. The method of any of clauses 11-14, including:
repeating bonding a respective silicon carbide wafer implanted with protons to the first semiconductor substrate to form a stack of a plurality of layers of silicon carbide.
16. The method of clause 15, wherein the plurality of layers of silicon carbide is interspersed with a plurality of layers of spin-on-glass.
17. The method of any of clauses 1-16, wherein the semiconductor substrate includes silicon.
18. The method of any of clauses 1-16, wherein the semiconductor substrate includes germanium.
19. A semiconductor device, comprising:
a semiconductor substrate;
a first layer of spin-on-glass positioned over the semiconductor substrate;
a first layer of silicon carbide positioned over the first layer of spin-on-glass;
a second layer of spin-on-glass positioned over the first layer of silicon carbide; and
a second layer of silicon carbide positioned over the second layer of spin-on-glass.
20. The semiconductor device of clause 19, further comprising:

a third layer of spin-on-glass positioned over the second layer of silicon carbide; and
a third layer of silicon carbide positioned over the third layer of spin-on-glass.
21. The semiconductor device of any of clauses 19-20, wherein a respective layer of silicon carbide has a concentration of protons in the respective layer of silicon carbide near a bottom surface of the respective layer of silicon carbide that is lower than a concentration of protons in the respective layer of silicon carbide near a top surface of the respective layer of silicon carbide, the bottom surface of the respective layer of silicon carbide being a planar surface facing the semiconductor substrate and the top surface of the respective layer of silicon carbide being a planar surface that is opposite to the bottom surface of the respective layer of silicon carbide.
22. The semiconductor device of any of clauses 19-21, wherein the second layer of silicon carbide has a concentration of protons in the second layer of silicon carbide near a bottom surface of the second layer of silicon carbide that is lower than a concentration of protons in the second layer of silicon carbide near a top surface of the second layer of silicon carbide, the bottom surface of the second layer of silicon carbide being a planar surface facing the semiconductor substrate and the top surface of the second layer of silicon carbide being a planar surface that is opposite to the bottom surface of the second layer of silicon carbide.
23. The semiconductor device of any of clauses 20-22, wherein the third layer of silicon carbide has a concentration of protons in the third layer of silicon carbide near a bottom surface of the third layer of silicon carbide that is lower than a concentration of protons in the third layer of silicon carbide near a top surface of the third layer of silicon carbide, the bottom surface of the third layer of silicon carbide being a planar surface facing the semiconductor substrate and the top surface of the third layer of silicon carbide being a planar surface that is opposite to the bottom surface of the third layer of silicon carbide.
24. The semiconductor device of any of clauses 19-23, further comprising an oxide layer positioned on the semiconductor substrate, wherein the first layer of spin-on-glass is positioned on the oxide layer on the semiconductor substrate.
25. The semiconductor device of any of clauses 19-23, further comprising a transistor, wherein the first layer of spin-on-glass is positioned over the transistor.

What is claimed is:

1. A method, comprising:
obtaining a first silicon carbide wafer implanted with protons;
applying a first layer of spin-on-glass over the first silicon carbide wafer;
obtaining a first semiconductor substrate;
bonding (i) the first layer of spin-on-glass applied over the first silicon carbide wafer to (ii) the first semiconductor substrate; and
heating the first silicon carbide wafer to initiate splitting of the first silicon carbide wafer so that a first layer of silicon carbide remains over the first semiconductor substrate.

2. The method of claim 1, further comprising:
prior to the bonding:
forming a first oxide layer on the first silicon carbide wafer; and,
subsequent to forming the first oxide layer on silicon carbide wafer, implanting the silicon carbide wafer with protons.

3. The method of claim 1, further comprising:
subsequent to splitting of the silicon carbide wafer, removing a portion of the silicon carbide wafer that is not bound to the first layer of spin-on-glass.

4. The method of claim 3, further comprising:
polishing the removed portion of the silicon carbide wafer;
forming a second oxide layer on the polished silicon carbide wafer;
subsequent to forming the second oxide layer on the polished silicon wafer, implanting the polished silicon carbide wafer with protons; and
bonding the polished silicon carbide wafer implanted with protons to a semiconductor substrate.

5. The method of claim 4, wherein bonding the polished silicon carbide wafer implanted with protons to the semiconductor substrate includes applying a second layer of spin-on-glass over the polished silicon carbide wafer and/or the semiconductor substrate.

6. The method of claim 4, further comprising:
heating the polished silicon carbide wafer to initiate splitting of the polished silicon carbide wafer so that a second layer of silicon carbide remains over the semiconductor substrate.

7. The method of claim 1, including:
bonding a second silicon carbide wafer implanted with protons to the first semiconductor substrate, wherein the second silicon carbide wafer is distinct from the first silicon carbide wafer.

8. The method of claim 7, wherein bonding the second silicon carbide wafer implanted with protons to the first semiconductor substrate includes applying a second layer of spin-on-glass over the polished silicon carbide wafer.

9. The method of claim 7, wherein bonding the second silicon carbide wafer implanted with protons to the first semiconductor substrate includes applying a second layer of spin-on-glass over the first semiconductor substrate.

10. The method of claim 7, further comprising:
heating the second silicon carbide wafer to initiate splitting of the second silicon carbide wafer so that a second layer of silicon carbide remains over the semiconductor substrate.

11. The method of claim 7, including:
repeating bonding a respective silicon carbide wafer implanted with protons to the first semiconductor substrate to form a stack of a plurality of layers of silicon carbide.

12. The method of claim 11, wherein the plurality of layers of silicon carbide is interspersed with a plurality of layers of spin-on-glass.

13. The method of claim 1, wherein the semiconductor substrate includes germanium.

14. A semiconductor device, comprising:
a semiconductor substrate;
a first layer of spin-on-glass positioned over the semiconductor substrate;
a first layer of silicon carbide positioned over the first layer of spin-on-glass;
a second layer of spin-on-glass positioned over the first layer of silicon carbide; and
a second layer of silicon carbide positioned over the second layer of spin-on-glass.

15. The semiconductor device of claim 14, further comprising:
a third layer of spin-on-glass positioned over the second layer of silicon carbide; and
a third layer of silicon carbide positioned over the third layer of spin-on-glass.

16. The semiconductor device of claim 14, wherein a respective layer of silicon carbide has a concentration of protons in the respective layer of silicon carbide near a bottom surface of the respective layer of silicon carbide that is lower than a concentration of protons in the respective layer of silicon carbide near a top surface of the respective layer of silicon carbide, the bottom surface of the respective layer of silicon carbide being a planar surface facing the semiconductor substrate and the top surface of the respective layer of silicon carbide being a planar surface that is opposite to the bottom surface of the respective layer of silicon carbide.

17. The semiconductor device of claim 14, wherein the second layer of silicon carbide has a concentration of protons in the second layer of silicon carbide near a bottom surface of the second layer of silicon carbide that is lower than a concentration of protons in the second layer of silicon carbide near a top surface of the second layer of silicon carbide, the bottom surface of the second layer of silicon carbide being a planar surface facing the semiconductor substrate and the top surface of the second layer of silicon carbide being a planar surface that is opposite to the bottom surface of the second layer of silicon carbide.

18. The semiconductor device of claim 15, wherein the third layer of silicon carbide has a concentration of protons in the third layer of silicon carbide near a bottom surface of the third layer of silicon carbide that is lower than a concentration of protons in the third layer of silicon carbide near a top surface of the third layer of silicon carbide, the bottom surface of the third layer of silicon carbide being a planar surface facing the semiconductor substrate and the top surface of the third layer of silicon carbide being a planar surface that is opposite to the bottom surface of the third layer of silicon carbide.

19. The semiconductor device of claim 14, further comprising an oxide layer positioned on the semiconductor substrate, wherein the first layer of spin-on-glass is positioned on the oxide layer on the semiconductor substrate.

20. The semiconductor device of claim 14, further comprising a transistor, wherein the first layer of spin-on-glass is positioned over the transistor.
